(19) United States
(12) Patent Application Publication
(10) Pub. No.: US 2024/0188339 A1
(43) Pub. Date: Jun. 6, 2024

(54) DISPLAY DEVICE AND MANUFACTURING METHOD THEREOF

(71) Applicant: Samsung Display Co., Ltd., Yongin-si (KR)

(72) Inventors: Hyuneok Shin, Yongin-si (KR); Juhyun Lee, Yongin-si (KR)

(73) Assignee: Samsung Display Co., Ltd., Yongin-si (KR)

(21) Appl. No.: 18/461,690

(22) Filed: Sep. 6, 2023

(30) Foreign Application Priority Data
Dec. 2, 2022 (KR) 10-2022-0167026

(51) Int. Cl. H10K 59/122; H10K 59/12; H10K 59/80; H10K 71/20

(52) U.S. Cl. CPC H10K 59/122; H10K 59/1201; H10K 59/879; H10K 71/233

(57) ABSTRACT

A display device includes a display panel including a display area, a plurality of transparent banks disposed over the display panel in the display area, including a first material having a first refractive index, and including a side surface contacting a second material having a second refractive index that is lower than the first refractive index, and an upper layer disposed on an upper surface of each of the plurality of transparent banks.

### CROSS-REFERENCE TO RELATED APPLICATION(S)

This application claims priority to and benefits of Korean Patent Application No. 10-2022-0167026 under 35 U.S.C. § 119, filed on Dec. 2, 2022, in the Korean Intellectual Property Office, the entire contents of which are incorporated herein by reference.

### BACKGROUND

### 1. Technical Field

One or more embodiments relate to a display device that filters emitted light transmitted in a certain direction among emitted light generated in a display panel, and a method of manufacturing the display device.

### 2. Description of the Related Art

A display device receives information of images and displays the images. Emitted light generated in a display panel included in the display device may be transmitted in various directions.

Thus, there is a demand for viewing angle control technology in which only light emitted in a straight direction among emitted light can be transmitted through an optical functional layer disposed over a display panel.

### SUMMARY

Embodiments solve various problems including the aforementioned problem and provide a display device that filters emitted light transmitted in a certain direction among emitted light generated in a display panel, and a method of manufacturing the display device.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a display device may include a display panel including a display area, a plurality of transparent banks disposed over the display panel in the display area, including a first material having a first refractive index, and including a side surface contacting a second material having a second refractive index that is lower than the first refractive index, and an upper layer disposed on an upper surface of each of the plurality of transparent banks.

The display device may further include a window layer disposed between the display panel and the plurality of transparent banks, the window layer having a third refractive index that is lower than the first refractive index.

The upper layer may have a fourth refractive index that is lower than the first refractive index, and the fourth refractive index may be higher than the third refractive index.

The fourth refractive index may be higher than the second refractive index.

The plurality of transparent banks may include niobium oxide (Nb₂O₅) or titanium oxide (TiOₓ).

The upper layer may include indium gallium zinc oxide (IGZO) or indium zinc oxide (IZO).

A distance between an upper surface of the upper layer and a lower surface of the upper layer may be less than a distance between an upper surface of each of the plurality of transparent banks and a lower surface of each of the plurality of transparent banks.

In a plan view, a width of an upper surface of each of the plurality of transparent banks may be less than a width of a lower surface of each of the plurality of transparent banks.

The plurality of transparent banks may include a first transparent bank, the upper layer may include a first upper layer disposed on an upper surface of the first transparent bank, and a side surface of the first transparent bank and a side surface of the first upper layer may form a continuous surface.

A thickness of each of the plurality of transparent banks may be greater than a thickness of the upper layer.

The plurality of transparent banks may include a plurality of beads including the first material.

According to one or more embodiments, a method of manufacturing a display device may include: in a display area of a display panel, forming, over the display panel, a first layer including a first material having a first refractive index, forming, on the first layer, a preliminary upper layer having a fourth refractive index that is lower than the first refractive index, patterning a photoresist disposed on the preliminary upper layer in a pattern having a certain shape, forming an upper layer by patterning the preliminary upper layer according to the pattern having the certain shape, forming a plurality of transparent banks by etching the first layer according to the pattern formed on the upper layer, and disposing a second material between the plurality of transparent banks, the second material having a second refractive index that is lower than the first refractive index.

The method may further include forming a window layer on the display panel before the first layer is formed, the window layer having a third refractive index that is lower than the first refractive index.

The upper layer may have a fourth refractive index that is lower than the first refractive index, and the fourth refractive index may be higher than the third refractive index.

The upper layer may have a fourth refractive index that is lower than the first refractive index, and the fourth refractive index may be higher than the second refractive index.

The first layer may include Nb₂O₅ or TiOₓ.

The upper layer may include IGZO or IZO.

The first layer may include a plurality of beads including the first material.

A distance between an upper surface of the upper layer and a lower surface of the upper layer may be less than a distance between an upper surface of the first layer and a lower surface of the first layer.

In a plan view, a width of an upper surface of each of the plurality of transparent banks may be less than a width of a lower surface of each of the plurality of transparent banks.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic plan view of a display panel of a display device according to an embodiment;

FIG. 2 is a schematic diagram of an equivalent circuit of a pixel included in the display panel of FIG. 1;

FIG. 3 is a schematic cross-sectional view of a portion of the display panel of FIG. 1;

FIG. 4 is a schematic cross-sectional view of a display device according to an embodiment;

FIG. 5 is a schematic cross-sectional view of a display device according to an embodiment;

FIG. 6 is a schematic cross-sectional view of an optical path centered on a transparent bank of a display device according to an embodiment;

FIG. 7 is a graph showing reflectance of a display device according to an embodiment;

FIG. 8 is a schematic cross-sectional view of a display device according to an embodiment; and

FIGS. 9 to 13 are schematic cross-sectional views showing in sequence a method of manufacturing a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, a display device according to one or more embodiments is described in detail, based on the above description.

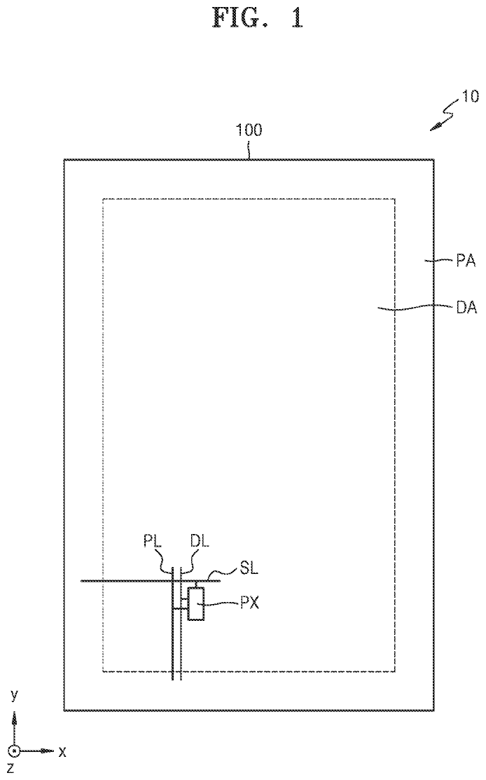

FIG. 1 is a schematic plan view of a display panel of a display device according to an embodiment.

As shown in FIG. 1, the display device may include a display panel 10. The display device including the display panel 10 may be any type of display device. For example, the display device may be various products such as a smartphone, a tablet computer, a laptop, a television, or a billboard. The display device may include thin-film transistors (TFTs), a capacitor, etc., and thus, the thin-film transistors (TFTs), the capacitor, and the like may be implemented by conductive layers and insulating layers.

The display panel 10 may include a display area DA and a peripheral area PA adjacent to the display area DA. FIG. 1 shows that the display area DA has a rectangular shape. However, one or more embodiments are not limited thereto. The display area DA may have various shapes, e.g., a circle, an oval, a polygon, and other specific shapes.

The display area DA may be an area where images are displayed, and pixels PX may be arranged in the display area DA. Each pixel PX may include a display element, such as an organic light-emitting diode. The pixel PX may emit, for example, red light, green light, or blue light. Such a pixel PX may be connected to a pixel circuit including a thin-film transistor (TFT), a storage capacitor, and the like. The pixel circuit may be connected to a scan line SL that transmits a scan signal, a data line DL intersecting the scan line SL and transmitting a data signal, a driving power line PL that supplies a driving voltage, and the like. The scan line SL may extend in an x-axis direction (hereinafter, referred to as a second direction), and the data line DL and the driving power line PL may each extend in a y-axis direction (hereinafter, referred to as a first direction).

The pixel PX may emit light having a brightness corresponding to an electrical signal transmitted from a pixel circuit electrically connected to the pixel PX. In the display area DA, certain images may be displayed by using light emitted from the pixel PX. For reference, the pixel PX may be defined as an emission area where any one of red light, green light, and blue light is emitted, as described above.

The peripheral area PA may be an area where no pixels P are arranged, and images are not displayed. In the peripheral area PA, a power supply line, etc. that drives the pixels PX may be positioned. For example, pads may be arranged in the peripheral area PA, and an integrated circuit device, for example, a printed circuit board or a driver IC including driving circuitry, may be electrically connected to the pads.

For reference, as the display panel 10 includes a substrate 100, it may be described that the substrate 100 includes the display area DA and the peripheral area PA. The substrate 100 is described below in detail.

For example, transistors may be arranged in the display area DA. According to types (e.g., an N-type or a P-type) and/or operation conditions of the transistors, a first terminal of a transistor may be a source electrode or a drain electrode, and a second terminal of the transistor may be an electrode that is different from the first terminal. For example, in case that the first terminal is a source electrode, the second terminal may be a drain electrode.

The transistors may include a driving transistor, a data write transistor, a compensation transistor, an initialization transistor, an emission control transistor, and the like. The driving transistor may be connected between the driving power line PL and an organic light-emitting diode OLED, and the data write transistor may be connected to the data line DL and the driving transistor and may perform a switching operation whereby a data signal transmitted through the data line DL is transmitted.

The compensation transistor may be turned on in response to a scan signal transmitted through the scan line SL and may compensate for a threshold voltage of the driving transistor by connecting the driving transistor to the organic light-emitting diode OLED.

The initialization transistor may be turned on in response to the scan signal transmitted through the scan line SL and initialize a gate electrode of the driving transistor by transmitting an initialization voltage to the gate electrode of the driving transistor. A scan line connected to the initialization transistor may be a separate scan line different from a scan line connected to the compensation transistor.

The emission control transistor may be turned on in response to an emission control signal transmitted through an emission control line, and thus, a driving current may flow in the organic light-emitting diode OLED.

The organic light-emitting diode OLED may include a pixel electrode (an anode) and an opposite electrode (a cathode), and an opposite electrode may receive a second power voltage ELVSS. The organic light-emitting diode OLED may emit light by receiving the driving current from the driving transistor, and thus, images may be displayed.

Hereinafter, an organic light-emitting display device is described as an example of the display device, but the display device is not limited thereto. As another example, the display device may be a display device such as an inorganic light-emitting display device, an inorganic EL display device, or a quantum dot light-emitting display device. For example, an emission layer of a display element of the display device may include an organic material or an inorganic material. For example, the display device may include an emission layer and quantum dots positioned in a path of light emitted from the emission layer.

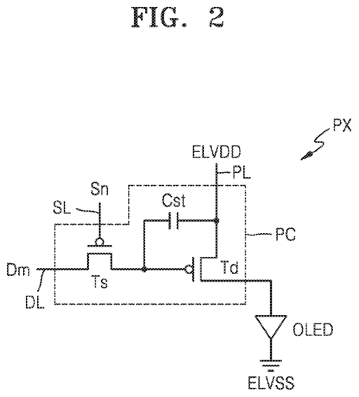

FIG. 2 is a schematic diagram of an equivalent circuit of a pixel included in the display panel 10 of FIG. 1.

As shown in FIG. 2, each pixel PX may include a pixel circuit PC connected to the scan line SL and the data line DL, and the organic light-emitting diode OLED connected to the pixel circuit PC. The pixel circuit PC may include a driving transistor Td, a switching transistor Ts, and a storage capacitor Cst. For example, the driving transistor Td and the switching transistor Ts may be thin-film transistors (TFTs). However, embodiments are not limited thereto. The switching transistor Ts may be connected to the scan line SL and the data line DL and may transmit a data signal Dm, which is input through the data line DL, to the driving transistor Td in response to a scan signal Sn that is input through the scan line SL.

The storage capacitor Cst may be connected to the switching transistor Ts and the driving power line PL and may store a voltage corresponding to a difference between a voltage from the switching transistor Ts and a first power voltage ELVDD provided to the driving power line PL. The second power voltage ELVSS may be a driving voltage having a relatively lower level than the first power voltage ELVDD. A level of the driving voltage supplied to each pixel PX may correspond to a level difference between the first power voltage ELVDD and the second power voltage ELVSS.

The driving transistor Td may be connected to the driving power line PL and the storage capacitor Cst and may control a driving current flowing in the organic light-emitting diode OLED from the driving power line PL according to the voltage stored in the storage capacitor Cst. The organic light-emitting diode OLED may emit light having a certain brightness due to the driving current.

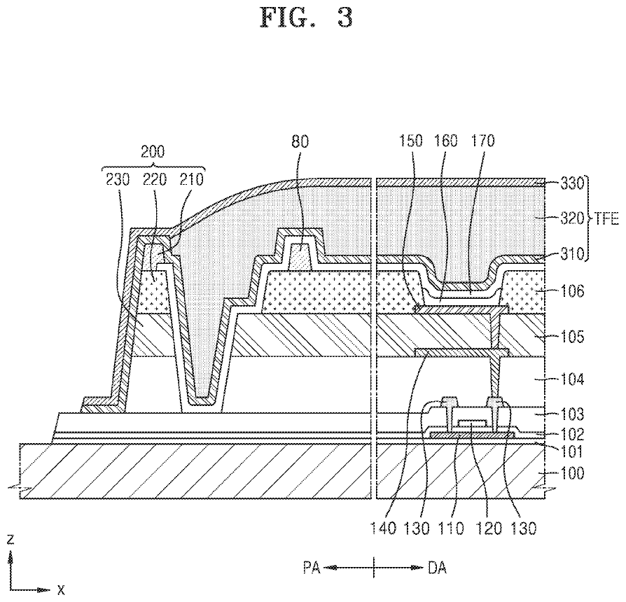

FIG. 3 is a schematic cross-sectional view of a portion of the display panel 10 of FIG. 1.

As described above, the substrate 100 may include areas corresponding to the display area DA and the peripheral area PA outside the display area DA. The substrate 100 may include various materials that are flexible or bendable. For example, the substrate 100 may include glass, metals, or polymer resin. For example, the substrate 100 may include polymer resin, such as polyethersulphone, polyacrylate, polyetherimide, polyethylene naphthalate, polyethylene terephthalate, polyphenylene sulfide, polyarylate, polyimide, polycarbonate, or cellulose acetate propionate. Various modifications may be made to the substrate 100, and for example, the substrate 100 may have a multilayered structure that includes two layers including the above polymer resin and a barrier layer including an inorganic material (e.g., silicon oxide, silicon nitride, silicon oxynitride, or the like) and arranged between the two layers.

A buffer layer 101 may be disposed over the substrate 100. The buffer layer 101 may prevent impurity ions from diffusing and moisture or external air from penetrating (or permeating) and may function as a barrier layer for flattening a surface and/or as a blocking layer. The buffer layer 101 may include silicon oxide, silicon nitride, or silicon oxynitride.

For example, the buffer layer 101 may adjust a heat supply speed during a crystallization process of forming a semiconductor layer 110, and thus, the semiconductor layer 110 may be evenly crystallized.

The semiconductor layer 110 may be disposed over the buffer layer 101. The semiconductor layer 110 may include polysilicon and include a channel area that is not doped with impurities and a source area and a drain area that are doped with impurities and arranged on both sides of the channel area. The impurities may differ according to types of thin-film transistors (TFTs) and may be N-type impurities (e.g., N-type dopants) or P-type impurities (e.g., P-type dopants).

A gate insulating layer 102 may be disposed over the semiconductor layer 110. The gate insulating layer 102 may ensure the insulation between the semiconductor layer 110 and a gate layer 120. The gate insulating layer 102 may include an inorganic material such as silicon oxide, silicon nitride, and/or silicon oxynitride and may be arranged between the semiconductor layer 110 and the gate layer 120. For example, the gate insulating layer 102 may correspond to the entire substrate 100 and may include contact holes in certain portions. An insulating layer including an inorganic material may be formed through a chemical vapor deposition (CVD) process or an atomic layer deposition (ALD) process, which is also applied to the embodiments below and modified examples thereof.

The gate layer 120 may be disposed over the gate insulating layer 102. The gate layer 120 may vertically overlap the semiconductor layer 110 and include at least one metal selected from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

An interlayer insulating layer 103 may be disposed over the gate layer 120. The interlayer insulating layer 103 may cover the gate layer 120. The interlayer insulating layer 103 may include an inorganic material. For example, the interlayer insulating layer 103 may include metal oxide or metal nitride. For example, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZrO₂). In some embodiments, the interlayer insulating layer 103 may have a dual structure including SiOₓ/SiN_{y} or SiNₓ/SiO_{y}.

A first conductive layer 130 may be disposed over the interlayer insulating layer 103. The first conductive layer 130 may function as an electrode connected to source/drain areas of a semiconductor layer through a through hole included in the interlayer insulating layer 103. The first conductive layer 130 may include one or more metals selected from among Al, Pt, Pd, Ag, Mg, Au, Ni, Nd, Ir, Cr, Li, Ca, Mo, Ti, W, and Cu. For example, the first conductive layer 130 may include a titanium layer, an aluminum layer, and/or a copper layer.

A first organic insulating layer 104 may be disposed over the first conductive layer 130. The first organic insulating layer 104 may cover an upper portion of the first conductive layer 130, may have a substantially flat upper surface, and thus may be an organic insulating layer that functions as a planarization layer. The first organic insulating layer 104 may include an organic material, for example, acryl, benzocyclobutene (BCB), hexamethyldisiloxane (HMDSO), or the like. Various modifications may be made to the first organic insulating layer 104. For example, the first organic insulating layer 104 may be a layer or layers.

A second conductive layer 140 may be disposed over the first organic insulating layer 104. The second conductive layer 140 may function as an electrode connected to source/drain areas of a semiconductor layer through a through hole included in the first organic insulating layer 104. The second conductive layer 140 may include one or more metals selected from among Al, Pt, Pd, Ag, Mg, Au, Ni, Nd, Ir, Cr, Li, Ca, Mo, Ti, W, and Cu. For example, the second conductive layer 140 may include a titanium layer, an aluminum layer, and/or a copper layer.

A second organic insulating layer 105 may be disposed over the first conductive layer 130. The second organic insulating layer 105 may cover an upper portion of the first conductive layer 130, may have a substantially flat upper surface, and thus may be an organic insulating layer that functions as a planarization layer. The second organic insulating layer 105 may include an organic material, for example, acryl, BCB, HMDSO, or the like. Various modifications may be made to the second organic insulating layer 105. For example, the second organic insulating layer 105 may be a layer or layers.

For example, an additional conductive layer and an additional insulating layer may be arranged between a conductive layer and a pixel electrode, and various embodiments may be made. For example, the additional conductive layer may include the same material and have the same layer structure as the conductive layer described above. The additional insulating layer may include the same material and have the same layer structure as the organic insulating layer described above.

A pixel electrode 150 may be disposed over the second organic insulating layer 105. The pixel electrode 150 may be connected to the second conductive layer 140 through a contact hole formed in the second organic insulating layer 105. A display element may be disposed over the pixel electrode 150. The organic light-emitting diode OLED may be used as the display element. For example, the organic light-emitting diode OLED may be disposed over, for example, the pixel electrode 150. The pixel electrode 150 may include a light-transmissive conductive layer including light-transmissive conductive oxide such as indium tin oxide (ITO), indium oxide (In₂O₃), or indium zinc oxide (IZO), and a reflection layer including a metal, such as Al or Ag. For example, the pixel electrode 150 may have a three-layer structure of ITO/Ag/ITO.

A pixel-defining layer 106 may be disposed over the second organic insulating layer 105 and arranged to cover edge portions of the pixel electrode 150. For example, the pixel-defining layer 106 may cover the edge portions of the pixel electrode 150. The pixel-defining layer 106 may have an opening corresponding to the pixel PX, and the opening may expose at least a central portion of the pixel electrode 150. The aforementioned pixel-defining layer 106 may include, for example, an organic material such as polyimide or HMDSO. For example, a spacer 80 may be disposed over the pixel-defining layer 106.

For example, the spacer 80 may be positioned in the peripheral area PA. In another example, the spacer 80 may be in the display area DA. The spacer 80 may prevent damage to the organic light-emitting diode OLED which is caused due to sagging (or bending) of a mask during the manufacturing procedure by using the mask. The spacer 80 may include an organic insulating material and may be a layer or layers.

An intermediate layer 160 and the opposite electrode 170 may be disposed over the opening of the pixel-defining layer 106. The intermediate layer 160 may include a low-molecular-weight material or a high-molecular-weight material. In case that the intermediate layer 160 includes a low-molecular-weight material, the intermediate layer 160 may include a hole injection layer, a hole transport layer, an emission layer, an electron transport layer, and/or an electron injection layer. In case that the intermediate layer 160 includes a high-molecular-weight material, the intermediate layer 160 may have a structure including the hole transport layer and the emission layer.

The opposite electrode 170 may include a light-transmissive conductive layer including light-transmissive conductive oxide such as ITO, In₂O₃, or IZO. The pixel electrode 150 may be used as an anode, and the opposite electrode 170 may be used as a cathode. The polarities of the pixel electrode 150 and the opposite electrode 170 may be applied in an opposite way.

The structure of the intermediate layer 160 is not limited to that described above and may vary. For example, at least one of layers forming the intermediate layer 160 may be integral with the opposite electrode 170 as a single body. In another example, the intermediate layer 160 may include layers patterned to correspond to (or overlap) the pixel electrodes 150, respectively.

The opposite electrode 170 may be disposed (e.g., entirely disposed) over the display area DA. For example, the opposite electrode 170 may be integrally formed to cover pixels. The opposite electrode 170 may electrically contact a common power supply line arranged in the peripheral area PA. In an embodiment, the opposite electrode 170 may extend to a barrier 200. A thin-film encapsulation layer TFE may cover (e.g., entirely cover) the display area DA, extend towards the peripheral area PA, and thus cover at least a portion of the peripheral area PA.

The thin-film encapsulation layer TFE may extend to the outside of the common power supply line. The thin-film encapsulation layer TFE may include a first inorganic encapsulation layer 310, a second inorganic encapsulation layer 330, and an organic encapsulation layer 320 arranged therebetween. The first inorganic encapsulation layer 310 and the second inorganic encapsulation layer 330 may each include one or more inorganic materials selected from among Al₂O₃, TiO₂, Ta₂O₅, HfO₂, ZnO, SiO₂, SiNₓ, and SiON.

The first inorganic encapsulation layer 310 and the second inorganic encapsulation layer 330 may each be a layer or layers including the above materials. The first inorganic encapsulation layer 310 and the second inorganic encapsulation layer 330 may include the same material or different materials. A thickness of the first inorganic encapsulation layer 310 may be different from that of the second inorganic encapsulation layer 330. The thickness of the first inorganic encapsulation layer 310 may be greater than the thickness of the second inorganic encapsulation layer 330. In another example, the thickness of the second inorganic encapsulation layer 330 may be greater than or the same as that of the first inorganic encapsulation layer 310.

The organic encapsulation layer 320 may include a monomer-based material or a polymer-based material. The polymer-based material may include acrylic resin, epoxy-based resin, polyimide, polyethylene, and the like. In an embodiment, the organic encapsulation layer 320 may include acrylate.

The barrier 200 may be positioned in the peripheral area PA of the substrate 100. In an embodiment, the barrier 200 may include a portion of the first organic insulating layer 104, a portion 230 of the second organic insulating layer 105, a portion 220 of the pixel-defining layer 106, and a portion 210 of the spacer 80, but one or more embodiments are not limited thereto.

In some cases, the barrier 200 may include the portion 230 of the second organic insulating layer 105 and the portion 220 of the pixel-defining layer 106. The barrier 200 may surround the display area DA and prevent the organic encapsulation layer 320 of the thin-film encapsulation layer TFE from overflowing towards the outer side of the substrate 100.

Therefore, the organic encapsulation layer 320 may contact an inner side surface of the barrier 200 that faces the display area DA. For example, the description that the organic encapsulation layer 320 contacts the inner side surface of the barrier 200 may indicate that the first inorganic encapsulation layer 310 is arranged between the organic encapsulation layer 320 and the barrier 200 and the organic encapsulation layer 320 contacts the first inorganic encapsulation layer 310.

The first inorganic encapsulation layer 310 and the second inorganic encapsulation layer 330 may be disposed over the barrier 200 and extend towards the edge portions of the substrate 100. In some cases, however, the barrier 200 may be provided in plural.

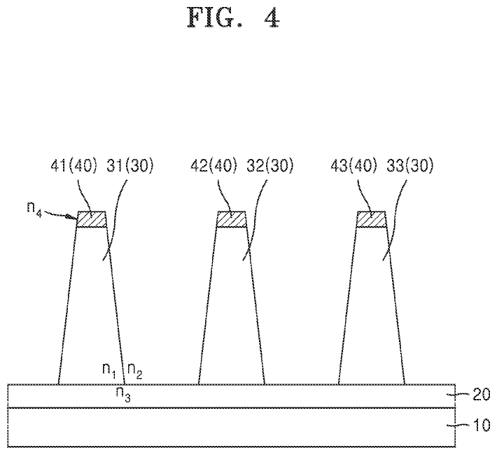

FIG. 4 is a schematic cross-sectional view of a display device according to an embodiment.

As shown in FIG. 4, the display device may include the display panel 10, transparent banks (or transparent partitions) 30, and an upper layer 40. For example, the display device may further include a window layer 20.

As described above, the display panel 10 may include the display area DA, and light may be externally emitted through the display area DA. The display panel 10 may externally display visual information through the display area DA.

The transparent banks 30 may be disposed over the display panel 10 in the display area DA. The transparent banks 30 may include transparent materials. The transparent banks 30 may include first materials having a first refractive index n₁. For example, the first material may be niobium oxide (Nb₂O₅) or TiOₓ. For example, the transparent banks 30 may include Nb₂O₅ or TiOₓ.

The transparent banks 30 may at least include a first transparent bank 31, a second transparent bank 32, and a third transparent bank 33. A second material 50 may be positioned between the first transparent bank 31 and the second transparent bank 32, the second material 50 having a second refractive index n₂ that is lower than the first refractive index n₁. For example, the second material 50 may be arranged between respective transparent banks 30. For example, the second material 50 may include an air layer component or an atmospheric layer component, and the second refractive index n₂ may be a refractive index of air at room temperature. A value of the second refractive index n₂ may be about 1.0003, which is determined based on a refractive index of 1 in vacuum space. The second refractive index n₂ may be higher than or equal to about 1 and lower than or equal to about 1.8.

Nb₂O₅ or TiOₓ, which has a high refractive index and is transparent, may be a material capable of inducing the Fresnel reflection. For example, the transparent banks 30 may be a type of optical filter disposed over the display panel 10 and may filter vertical light or light equivalent to the vertical light with respect to an upper surface of the display panel 10. For example, a material having the second refractive index n₂ or a second prime refractive index n₂′ may be arranged between the transparent banks 30, and the second material 50 or a second prime material 50 may be a material, such as air or glass, and have a refractive index ranging from about 1 to about 1.5. A refractive index, which is sufficiently greater than the second material 50 or the second prime material 50, may be between about 2 and about 2.5, and a material having the greater refractive index may be Nb₂O₅ or TiOₓ.

Each of the transparent banks 30 may have a lower surface contacting the display panel 10 and an upper surface arranged opposite to the lower surface. When viewed in a direction perpendicular to the display panel 10 (or in a plan view), an area of the upper surface of each transparent bank 30 may be less than that of the lower surface thereof. As a result, in a cross-sectional view, each transparent bank 30 may have a trapezoid shape.

For example, the distance between the first transparent bank 31 and the second transparent bank 32 may decrease as being closer to the display panel 10, but may increase as being farther from the display panel 10. The distance between the second transparent bank 32 and the third transparent bank 33 may also have the above-described characteristics. For example, distances between other transparent banks may also have the above-described characteristics.

The window layer 20 may be arranged between the display panel 10 and the transparent banks 30. The window layer 20 may be a polymer layer including polyethylene terephthalate (PET) or polyimide. In another example, the window layer 20 may be a glass layer including ultra-thin glass (UTG). The window layer 20 may have a third refractive index n₃ lower than the first refractive index n₁. For example, the window layer 20 may include a material having the third refractive index n₃ that is lower than the first refractive index n₁.

When viewed in the direction perpendicular to the upper surface of the display panel 10 (or in a plan view), an area (or size) of the window layer 20 may be greater than or equal to an area (or size) of the display panel 10 such that the window layer 20 may protect the display panel 10 from the outside.

The upper layer 40 may be disposed over the upper surface of each transparent bank 30. The upper layer 40 may include a transparent material and have a fourth refractive index n₄ that is lower than the first refractive index n₁. The fourth refractive index n₄ may be higher than the third refractive index n₃. The fourth refractive index n₄ may be higher than the second refractive index n₂. The fourth refractive index n₄ may be higher than a second prime refractive index n₂′ described below.

The upper layer 40 may include a transparent conductive material. For example, the transparent conductive material may include IGZO, IZO, or ITO. The transparent conductive material may include a material having the fourth refractive index n₄. For example, the fourth refractive index n₄ of a fourth material may be about 2.0.

On the transparent banks 30, the upper layer 40 may function as a hard mask for covering the upper surfaces of the transparent banks 30, respectively. For example, the upper layer 40 may be a hard mask layer having patterns corresponding to the transparent banks 30, respectively. As the upper layer 40 functions as the hard mask, the upper layer 40 may remain on the upper surface of each transparent bank 30 after an etching process. To function as the hard mask, the upper layer 40 may include a transparent conductive material, for example, IGZO, IZO, or ITO, which has a relatively lower etch rate.

Throughout the description, however, the description regarding a comparison of etch rates or selectivities may refer to a comparison of etch rates or selectivities of different materials in the same process under the same conditions.

IGZO, IZO, or ITO may not be etched through dry etching, and thus, the upper layer 40 including the above material may function as a hard mask in case that the transparent banks 30 are formed through dry etching. For example, the fourth material may have a lower etch rate than the first material during the dry etching. In another example, the fourth material may have a higher selectivity than the first material during the dry etching.

A thickness of the upper layer 40 may be less than a height (or thickness) of each transparent bank 30. The thickness may indicate a thickness in a direction perpendicular to the upper surface of the display panel 10, and the height (or thickness) may indicate a length from a lower surface of a component to an upper surface thereof. As the thickness of the upper layer 40 is less than the height (or thickness) of each transparent bank 30, the upper layer 40 may remain on the upper surface of each transparent bank 30 and thus function as a hard mask. For example, the thickness of the upper layer 40 may be about 300 Å, and the height (or thickness) of each transparent bank 30 may be about 1 um.

For example, the upper layer 40 may remain on the upper surface of each transparent bank 30 and may function as a hard mask during a dry etching process of forming the transparent banks 30, but as the upper layer 40 includes a transparent material, the upper layer 40 may not affect the Fresnel reflection.

The upper layer 40 may at least include a first upper layer 41, a second upper layer 42, and a third upper layer 43. The first upper layer 41 may be disposed over the first transparent bank 31. The second upper layer 42 may be disposed over the second transparent bank 32. The third upper layer 43 may be disposed over the third transparent bank 33. For example, a side surface of the first upper layer 41 and a side surface of the first transparent bank 31 may be coplanar with each other, and may form a continuous surface. For example, a side surface of the second upper layer 42 and a side surface of the second transparent bank 32 may be coplanar with each other, and may form a continuous surface. For example, a side surface of the third upper layer 43 and a side surface of the third transparent bank 33 may be coplanar with each other, and may form a continuous surface.

The first upper layer 41 may include a lower surface contacting the first transparent bank 31 and an upper surface arranged opposite to the lower surface. When viewed in the direction perpendicular to the display panel 10 (or in a plan view), an area (or size) of the upper surface of the first upper layer 41 may be less than an area (or size) of the lower surface thereof. As a result, in a cross-sectional view, the first upper layer 41 may have a trapezoid shape. Such a shape characteristic may also be applied to the second upper layer 42 and the third upper layer 43. For example, the shape characteristic may be applied to other upper layers.

For example, the distance between the first upper layer 41 and the second upper layer 42 may decrease as being closer to the display panel 10, but may increase as being farther from the display panel 10. The distance between the second upper layer 42 and the third upper layer 43 may also have the above-described characteristics. For example, distances between other upper layers may also have the above-described characteristics.

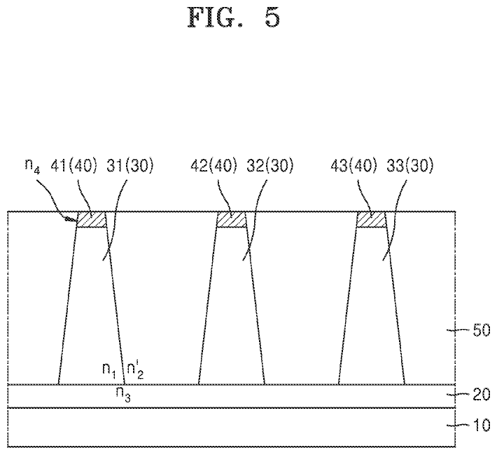

FIG. 5 is a schematic cross-sectional view of a display device according to an embodiment.

As shown in FIG. 5, the transparent banks 30 may at least include the first transparent bank 31, the second transparent bank 32, and the third transparent bank 33. A second prime material 50 may be positioned between the first transparent bank 31 and the second transparent bank 32, the second prime material 50 having a second prime refractive index n₂′ that is lower than the first refractive index n₁. For example, the second prime material 50 may be arranged between respective transparent banks 30. For example, the second prime material 50 may include a transparent material, such as a glass component or a polyamide component, e.g., polyamide (PI).

The second prime refractive index n₂′ may be about 1.5. The second prime refractive index n₂′ may be lower than the first refractive index n₁, higher than the second refractive index n₂, and lower than the fourth refractive index n₄.

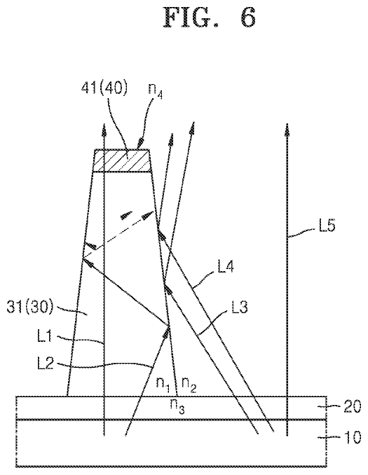

FIG. 6 is a schematic cross-sectional view of an optical path centered on a first transparent bank of a display device according to an embodiment.

As shown in FIG. 6, each transparent bank 30 (e.g., the first transparent bank 31 in FIG. 6) may have the first refractive index n₁, the second material 50 disposed between the transparent banks 30 may have the second refractive index n₂, and in case that the first refractive index n₁ is higher than the second refractive index n₂, the Fresnel reflection may occur.

First light L1, which is emitted in a direction perpendicular to the upper surface of the display panel 10 among light emitted towards the inside of the first transparent bank 31 in the display panel 10, may directly pass through the first transparent bank 31. For example, an angle of incidence (or incident angle) of the first light L1 may be about 90° and may directly pass through the first transparent bank 31.

Second light L2 may be emitted towards an inner side surface of the first transparent bank 31 in the display panel 10 and may have an incident angle that is greater than or equal to a critical angle. For example, the second light L2 may be reflected again to the inside of the first transparent bank 31 due to the Fresnel reflection. As a result, the second light L2 may disappear (or be diminished) inside the first transparent bank 31.

Third light L3 may be emitted towards an outer side surface of the first transparent bank 31 in the display panel 10, a portion of the third light L3 may be refracted to the inside of the first transparent bank 31, and another portion of the third light L3 may be reflected to the outside of the first transparent bank 31. The portion of the third light L3, which is refracted towards the inside of the first transparent bank 31, may disappear (or be diminished) inside the first transparent bank 31.

Fourth light L4 may be emitted towards an outer side surface of the first transparent bank 31 in the display panel 10 and may have an incident angle that is greater than or equal to a critical angle. For example, the fourth light L4 may be reflected to the outside of the first transparent bank 31 due to the Fresnel reflection. For example, the fourth light L4 may be reflected at an angle close to the vertical light, and as a result, the fourth light L4 that is emitted at an oblique angle may be filtered.

Fifth light L5 may be directly emitted without being filtered in the display panel 10 as vertical light emitted in the direction perpendicular to the display panel 10.

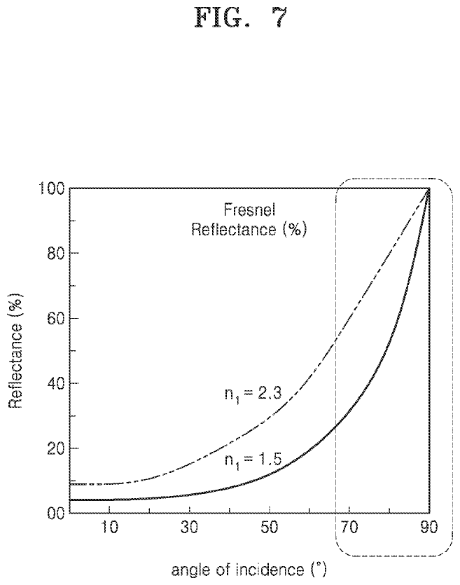

FIG. 7 is a graph showing reflectance of a display device according to an embodiment. The graph of FIG. 7 shows the reflectance of the display device according to a first refractive index n₁ of a first material in case that a second material 50 is air at room temperature.

As shown in FIG. 7, it is identified that the Fresnel reflectance is higher in case that the first refractive index n₁ is about 2.3, compared to that the first refractive index n₁ of the first material included in the transparent banks 30 is about 1.5. For example, in case that the incident angle is equal to or greater than about 70°, the reflectance may be higher in case that the first refractive index n₁ is about 2.3.

In case that the first refractive index n₁ is about 2.3, light, which is incident at an angle oblique to side surfaces of the transparent banks 30, may have higher reflectance, compared to that the first refractive index n₁ is about 1.5. The first material having the first refractive index n₁ of about 2.3 or a refractive index similar to the first refractive index n₁ may be Nb₂O₅ or TiOₓ that is described above. Nb₂O₅ may have an advantage over TiOₓ in case that a thick layer having a thickness of about 1 um is formed during a sputtering process, and thus, the first material may be Nb₂O₅.

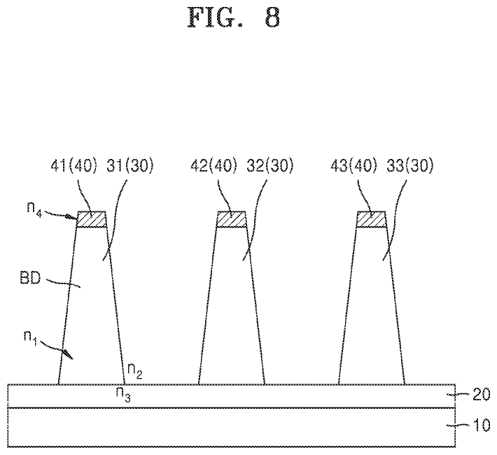

FIG. 8 is a schematic cross-sectional view of a display device according to an embodiment.

As shown in FIG. 8, the transparent banks 30 may include beads BD including the first materials having the first refractive index n₁. The first material may be Nb₂O₅ or TiOₓ, and TiOₓ may be a material difficult to be used to form a thick layer having a thickness of equal to or greater than about 1 um (about 4 um to about 5 um). In case that the beads BD are used, the transparent banks 30 having a thickness of equal to or greater than about 1 um may be formed by using TiOₓ. Therefore, as the transparent banks 30 of the display device according to an embodiment include the beads BD, there would be no thickness limitation that may be imposed during the sputtering process.

For example, the display device formed with the beads BD may have advantages as the transparent banks 30 having intended optical properties may be formed by controlling the number or density of the beads BD respectively included in the transparent banks 30.

Although the transparent banks 30 may have weak optical properties as compared to that all of the transparent banks 30 include the first material, the weakness may be solved by increasing the number or density of the beads BD.

Hereinafter, a method of manufacturing a display device according to one or more embodiments (hereinafter, referred to as a manufacturing method) is described in detail below, based on the above description.

For reference, the same description or similar description as that regarding the display device may be omitted for descriptive convenience.

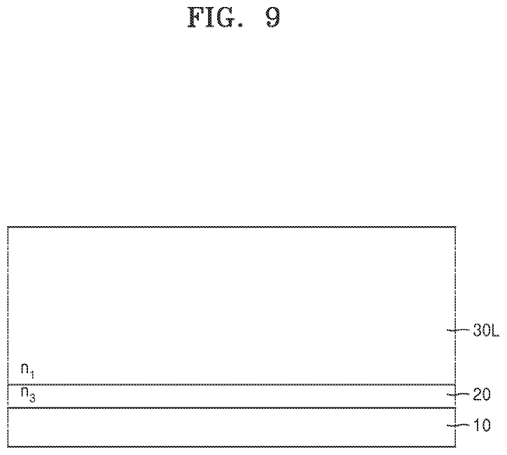

FIGS. 9 to 13 are schematic cross-sectional views showing in sequence a method of manufacturing a display device according to an embodiment.

As shown in FIG. 9, the manufacturing method according to an embodiment may include forming, over the display panel 10, a first layer 30L including a first material having a first refractive index n₁, in a display area of the display panel 10. In the forming of the first layer 30L, the first layer 30L may be formed over the display panel 10 after the display panel 10 is prepared. The first layer 30L may be formed by, e.g., a CVD process, an ALD process, or a sputtering process. The first layer 30L may include Nb₂O₅ or TiOₓ. For example, the first material may include Nb₂O₅ or TiOₓ.

In some cases, the first layer 30L may include the beads BD including the first material. As the description regarding the beads BD is the same as that provided with reference to FIG. 8, the same or similar description is omitted for descriptive convenience.

For example, a window layer 20 may be arranged between the display panel 10 and the first layer 30L, and as the description regarding the window layer 20 is the same as that provided above, the same or similar description regarding the window layer 20 is omitted for descriptive convenience. For example, in the manufacturing method according to an embodiment, the window layer 20 having the third refractive index n₃, which is lower than the first refractive index n₁, may be formed on the display panel 10. For example, the forming of the first layer 30L may indicate forming the first layer 30L on the window layer 20.

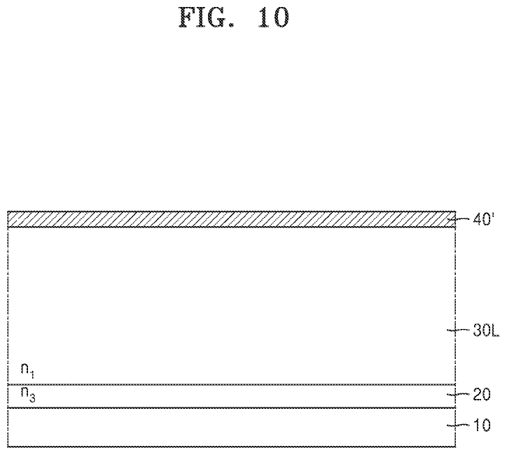

As shown in FIG. 10, the manufacturing method according to an embodiment may include forming a preliminary upper layer 40′ after the first layer 30L is formed. The preliminary upper layer 40′ may have a certain thickness and may be formed by, e.g., a CVD process, an ALD process, or a sputtering process.

For example, a distance (or thickness) between an upper surface of the preliminary upper layer 40′ and a lower surface thereof may be less than a distance (or thickness) between an upper surface of the first layer 30L and a lower surface thereof. For example, the thickness of the preliminary upper layer 40′ may be less than that of the first layer 30L. As the preliminary upper layer 40′ is etched to form an upper layer 40 having a pattern of a certain shape as in the process below, the upper layer 40 may function as a hard mask in case that the first layer 30L is etched.

For example, the upper layer 40 may have a fourth refractive index n₄ that is lower than the first refractive index n₁ of the first material. For example, the upper layer 40 may include a transparent conductive material. For example, the transparent conductive material may include IGZO, IZO, or ITO. The transparent conductive material may include a material having the fourth refractive index n₄. For example, the fourth refractive index n₄ of the fourth material may be about 2.0.

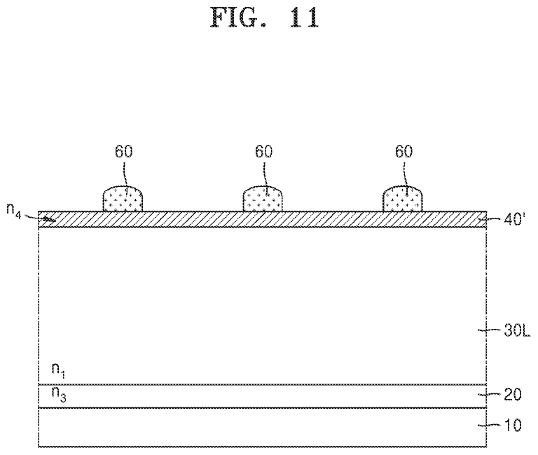

As shown in FIG. 11, the manufacturing method according to an embodiment may include patterning, on the preliminary upper layer 40′, a photoresist 60 in a pattern having a certain shape after the preliminary upper layer 40′ is formed. The patterning of the photoresist 60 in the pattern having the certain shape may include a photolithography process using a mask and an etching process. In the photolithography process, a negative photoresist or a positive photoresist may be used.

According to light transmittance, the mask may be divided into a transmission area where light is transmitted, and a light-shielding area where the light transmission is prevented. In some cases, however, a halftone mask, etc. may be used, and types of masks may vary, and embodiments are not limited by types of masks.

A patterning process is as follows. For example, after a photoresist (e.g., negative photoresist) 60 is spread on the upper layer 40, the photoresist 60 may be exposed to light by using a mask and developed. A first portion of the photoresist 60, which corresponds to the transmission area of the mask, may not be removed and remain thick, and a second portion of the photoresist 60, which corresponds to the light-shielding area of the mask, may be removed (e.g., entirely removed) as the second portion is not exposed to light.

The upper layer 40 may be over-etched. The upper layer 40 may be over-etched to have an oblique lateral structure and may have an inclined surface with an angle of less than 900.

The upper layer 40 may have the fourth refractive index n₄ that is lower than the first refractive index n₁. For example, the fourth refractive index n₄ may be higher than the third refractive index n₃. For example, the fourth refractive index n₄ may be higher than the second refractive index n₂.

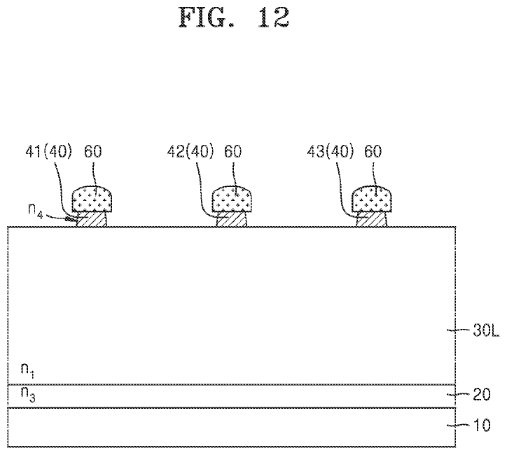

As shown in FIG. 12, the manufacturing method according to an embodiment may include forming the upper layer 40 according to the pattern having the certain shape by performing a first etching process, after the photoresist 60 is patterned.

As described above, the first etching process may be a process of etching the upper layer 40 in the pattern of the photoresist 60 that is already formed. Through the first etching process using an etchant, the upper layer 40 having the pattern of the certain shape may be formed in an area corresponding to the above-described first portion.

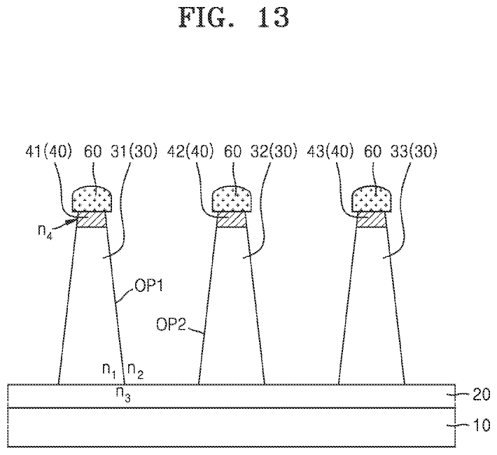

As shown in FIG. 13, the manufacturing method according to an embodiment may include forming, in the first layer 30L, the transparent banks 30 by performing a second etching process, according to the pattern formed on the upper layer 40. For example, the forming of the transparent banks 30 may be an operation of etching the first layer 30L by using the upper layer 40 as a hard mask.

As described above, the second etching process may be a process of etching the first layer 30L in the pattern of the upper layer 40 that is already formed. Through the second etching process by using an etchant, the transparent banks 30 may be formed in an area corresponding to the pattern of the upper layer 40 that is already formed. For example, the second etching process may be the same as the first etching process, and the second etching process and the first etching process may be performed at the same time. In another example, the second etching process may be a separate process from the first etching process and may use an etchant different from that used during the first etching process, and the second etching process may be performed independently from the first etching process.

In the forming of the transparent banks 30, openings may be formed in the first layer 30L. As the openings are formed, the transparent banks 30 may be formed. For example, the openings may be defined by the transparent banks 30.

A first opening OP1 may be arranged between the first transparent bank 31 and the second transparent bank 32. A second opening OP2 may be arranged between the second transparent bank 32 and the third transparent bank 33. For example, other openings may be further arranged between other transparent banks.

In the openings, the second material 50 having the second refractive index n₂ may be arranged. For example, the manufacturing method according to an embodiment may further include arranging (or disposing) the second material 50 having the second refractive index n₂, which is lower than the first refractive index n₁, between the transparent banks 30 (see, e.g., FIG. 5). For example, the second material 50 may be formed as a separate transparent layer, but may be arranged between the transparent banks 30 in case that the display device is naturally suspended in the air as an air layer.

For example, as described above, the second refractive index n₂ may be lower than the first refractive index n₁. As the second refractive index n₂ is lower than the first refractive index n₁, the Fresnel reflection may be induced.

The features described with regard to the display device according to one or more embodiments include the features described with regard to the manufacturing method according to an embodiment.

According to the one or more embodiments, a display device capable of filtering emitted light transmitted in a specific direction among emitted light generated in a display panel and a method of manufacturing the display device may be implemented. However, embodiments are not limited by the effects.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a display panel comprising a display area;
a plurality of transparent banks disposed over the display panel in the display area, comprising a first material having a first refractive index, and comprising a side surface contacting a second material having a second refractive index that is lower than the first refractive index; and
an upper layer disposed on an upper surface of each of the plurality of transparent banks.

2. The display device of claim 1, further comprising:
a window layer disposed between the display panel and the plurality of transparent banks, the window layer having a third refractive index that is lower than the first refractive index.

3. The display device of claim 2, wherein
the upper layer has a fourth refractive index that is lower than the first refractive index, and
the fourth refractive index is higher than the third refractive index.

4. The display device of claim 1, wherein
the upper layer has a fourth refractive index that is lower than the first refractive index, and
the fourth refractive index is higher than the second refractive index.

5. The display device of claim 1, wherein the plurality of transparent banks comprise niobium oxide (Nb₂O₅) or titanium oxide (TiOₓ).

6. The display device of claim 1, wherein the upper layer comprises indium gallium zinc oxide (IGZO) or indium zinc oxide (IZO).

7. The display device of claim 1, wherein a distance between an upper surface of the upper layer and a lower surface of the upper layer is less than a distance between an upper surface of each of the plurality of transparent banks and a lower surface of each of the plurality of transparent banks.

8. The display device of claim 1, wherein, in a plan view, a width of an upper surface of each of the plurality of transparent banks is less than a width of a lower surface of each of the plurality of transparent banks.

9. The display device of claim 8, wherein
the plurality of transparent banks comprise a first transparent bank,
the upper layer comprises a first upper layer disposed on an upper surface of the first transparent bank, and
a side surface of the first transparent bank and a side surface of the first upper layer form a continuous surface.

10. The display device of claim 1, wherein a thickness of each of the plurality of transparent banks is greater than a thickness of the upper layer.

11. The display device of claim 1, wherein the plurality of transparent banks comprise a plurality of beads comprising the first material.

12. A method of manufacturing a display device, the method comprising:
in a display area of a display panel, forming, over the display panel, a first layer comprising a first material having a first refractive index;
forming, on the first layer, a preliminary upper layer having a fourth refractive index that is lower than the first refractive index;
patterning a photoresist disposed on the preliminary upper layer in a pattern having a certain shape;
forming an upper layer by patterning the preliminary upper layer according to the pattern having the certain shape;
forming a plurality of transparent banks by etching the first layer according to a pattern of the upper layer; and
disposing a second material between the plurality of transparent banks, the second material having a second refractive index that is lower than the first refractive index.

13. The method of claim 12, further comprising:
forming a window layer on the display panel before the first layer is formed,
wherein the window layer has a third refractive index that is lower than the first refractive index.

14. The method of claim 13, wherein
the upper layer has a fourth refractive index that is lower than the first refractive index, and
the fourth refractive index is higher than the third refractive index.

15. The method of claim 12, wherein
the upper layer has a fourth refractive index that is lower than the first refractive index, and
the fourth refractive index is higher than the second refractive index.

16. The method of claim 12, wherein the first layer comprises niobium oxide (Nb₂O₅) or titanium oxide (TiOₓ).

17. The method of claim 12, wherein the upper layer comprises indium gallium zinc oxide (IGZO) or indium zinc oxide (IZO).

18. The method of claim 12, wherein the first layer comprises a plurality of beads comprising the first material.

19. The method of claim 12, wherein a distance between an upper surface of the upper layer and a lower surface of the upper layer is less than a distance between an upper surface of the first layer and a lower surface of the first layer.

20. The method of claim 12, wherein, in a plan view, a width of an upper surface of each of the plurality of transparent banks is less than a width of a lower surface of each of the plurality of transparent banks.
